(19) United States
(12) Patent Application Publication
(10) Pub. No.: US 2023/0412182 A1
(43) Pub. Date: Dec. 21, 2023

(54) AD CONVERTER

(71) Applicant: ROHM Co., LTD., Kyoto (JP)

(72) Inventor: Koji Saito, Kyoto (JP)

(21) Appl. No.: 18/337,138

(22) Filed: Jun. 19, 2023

(30) Foreign Application Priority Data
Jun. 20, 2022 (JP) 2022-098791

(51) Int. Cl. H03M 1/06

(52) U.S. Cl. CPC H03M 1/0604

(57) ABSTRACT

Provided is an AD converter including a capacitive DAC, a comparator, and a control logic unit. The capacitive DAC includes first bit capacitors connected in parallel to a first line, second bit capacitors connected in parallel to at least one second line, a connection capacitor connecting the first line and the second line, an adjustment capacitor connected to the second line, and a bit correction unit corresponding to at least either the first bit capacitors or the second bit capacitors. The bit correction unit includes a correction capacitor including a first terminal connected to at least one of the first line and the second line. A voltage can be applied to a second terminal of the correction capacitor in conjunction with a first bit capacitor or second bit capacitor corresponding to the correction capacitor among the first bit capacitors and the second bit capacitors.

### CROSS REFERENCE TO RELATED APPLICATIONS

This application claims priority benefit of Japanese Patent Application No. JP 2022-098791 filed in the Japan Patent Office on Jun. 20, 2022. Each of the above-referenced applications is hereby incorporated herein by reference in its entirety.

### BACKGROUND

The present disclosure relates to an analog-to-digital (AD) converter.

In related art, analog-to-digital converters (ADCs) that convert analog signals into digital signals have been applied to various systems. There is a successive-approximation ADC as a type of ADC (see Japanese Patent Laid-Open No. 2014-103438, for example).

### BRIEF DESCRIPTION OF THE DRAWINGS

FIG. 1 is a block diagram illustrating a configuration of an ADC according to a first embodiment of the present disclosure;

FIG. 2 is a diagram illustrating a configuration of a capacitive digital-to-analog converter (DAC) according to a first comparative example;

FIG. 3 is a diagram illustrating a configuration of a capacitive DAC according to a second comparative example;

FIG. 4 is a diagram illustrating an example of a configuration of a capacitive DAC according to the first embodiment of the present disclosure;

FIG. 5 is a diagram illustrating a capacitance correction control method;

FIG. 6 is a diagram illustrating the capacitance correction control method;

FIG. 7 is a diagram illustrating a correspondence relation between an analog input voltage and a code of a digital output;

FIG. 8 is a diagram illustrating a correspondence relation between the analog input voltage and the code of the digital output;

FIG. 9 is a diagram illustrating an example of a configuration for adjusting a connection capacitor illustrated in FIG. 4;

FIG. 10 is a diagram illustrating a sequence of an AD conversion process including a re-search process;

FIG. 11 is a diagram illustrating an example of the transition of the digital-to-analog (DA) conversion output of the capacitive DAC in the successive conversion including re-search;

FIG. 12 is a diagram illustrating a voltage application control method in a process including re-search;

FIG. 13 is a diagram illustrating a configuration for processing a re-search result;

FIG. 14 is a table indicating a conversion process in a decoder;

FIG. 15A is a diagram illustrating an example of a configuration of a control logic unit;

FIG. 15B is a diagram illustrating an example of a configuration of the capacitive DAC;

FIG. 15C is a diagram illustrating a first example of an offset correction control method;

FIG. 15D is a diagram illustrating a second example of the offset correction control method;

FIG. 15E is a diagram illustrating an example of offset;

FIG. 16 is a diagram illustrating a configuration of the ADC according to a second embodiment;

FIG. 17 is a diagram illustrating a correspondence relation between an input voltage and the analog input voltage;

FIG. 18 is a diagram illustrating a correspondence relation between the analog input voltage and the digital output;

FIG. 19 is a diagram illustrating a configuration of a capacitive DAC according to a comparative example;

FIG. 20 is a diagram illustrating a configuration of the capacitive DAC according to the second embodiment;

FIG. 21 is a diagram illustrating the state at the time of sampling in the capacitive DAC according to the second embodiment;

FIG. 22 is a diagram illustrating an example of the state at the time of successive approximation in the capacitive DAC according to the second embodiment;

FIG. 23 is a diagram illustrating a configuration of the ADC according to a third embodiment of the present disclosure;

FIG. 24 is a diagram illustrating a sequence of the AD conversion process according to the third embodiment;

FIG. 25 is a diagram illustrating an example of a configuration of a flash ADC;

FIG. 26 is a diagram illustrating a conversion table used for a decoder in the flash ADC;

FIG. 27 is a diagram illustrating an example of the transition of the DA conversion output of the capacitive DAC at the time of successive approximation for each of the case where no flash ADC is provided (left side) and the case where the flash ADC is provided (right side); and

FIG. 28 is a diagram illustrating an example of a configuration of the control logic unit according to the third embodiment.

### DETAILED DESCRIPTION

Exemplary embodiments of the present disclosure are described below with reference to the drawings. An ADC described below is a successive-approximation ADC.

### First Embodiment

### Configuration of ADC

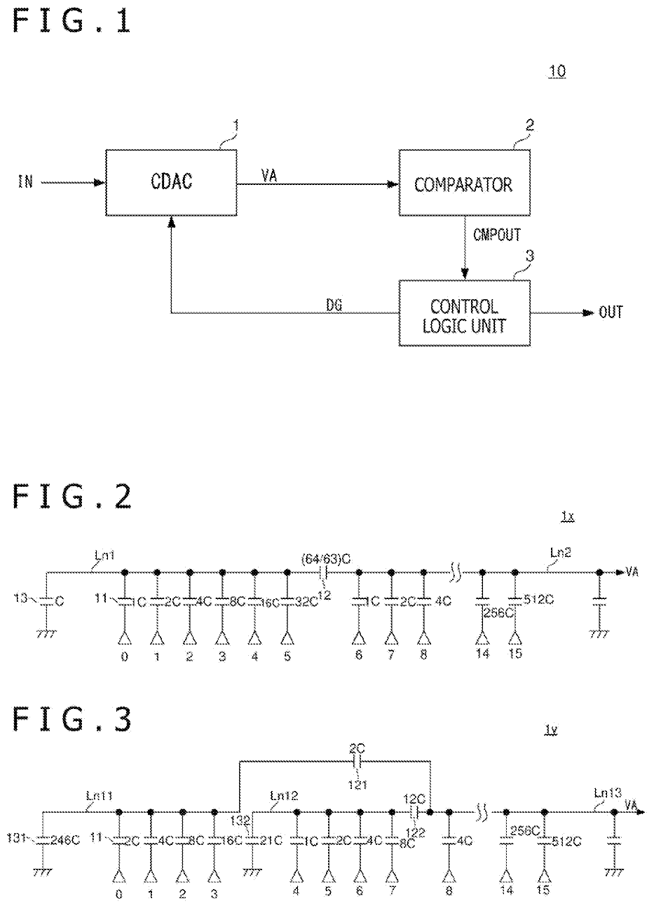

FIG. 1 is a block diagram illustrating a configuration of an ADC 10 according to a first embodiment of the present disclosure. The ADC 10 illustrated in FIG. 1 includes a capacitive DAC 1, a comparator 2, and a control logic unit 3. The ADC 10 generates a digital output OUT by performing AD conversion on an analog input voltage IN. The digital output OUT is a digital signal with a predetermined number of bits (e.g., 16 bits).

The capacitive DAC 1 generates an analog output voltage VA on the basis of a digital signal DG set by the control logic unit 3. The digital signal DG is a signal with the above-described predetermined number of bits. The capacitive DAC 1 also has a function to sample and hold the analog input voltage IN. The comparator 2 outputs a comparator output CMPOUT on the basis of the analog output voltage VA. The comparator output CMPOUT indicates a result of comparison between a DA conversion output obtained by performing DA conversion on the digital signal DG and the analog input voltage IN. The control logic unit 3 controls the capacitive DAC 1. The control logic unit 3 sets the digital signal DG according to the comparator output CMPOUT output from the comparator 2. The control logic unit 3 outputs the digital output OUT.

For example, the capacitive DAC 1 may include one DAC (single-ended type) into which one analog input voltage IN is input, and may input the output (analog output voltage VA) of the above-described DAC into a first input terminal of the comparator 2 and apply a ground potential to a second input terminal of the comparator 2.

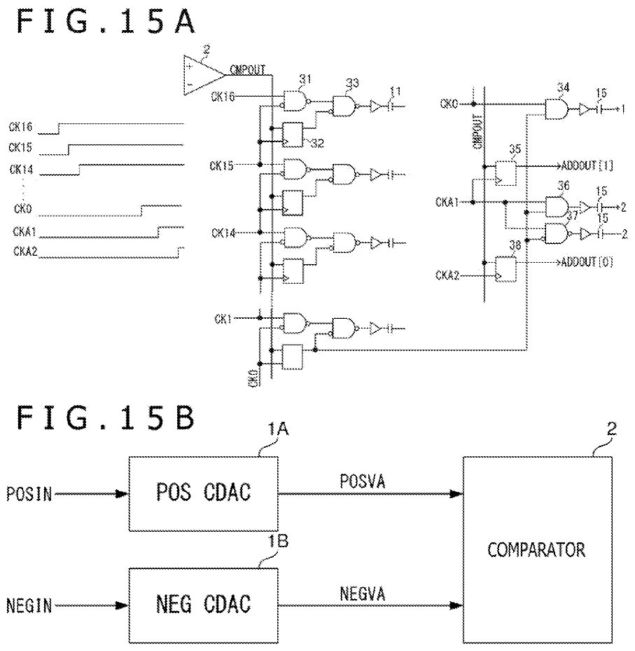

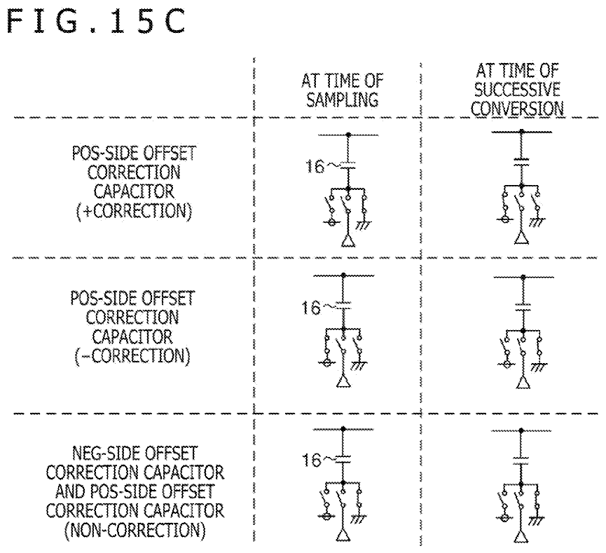

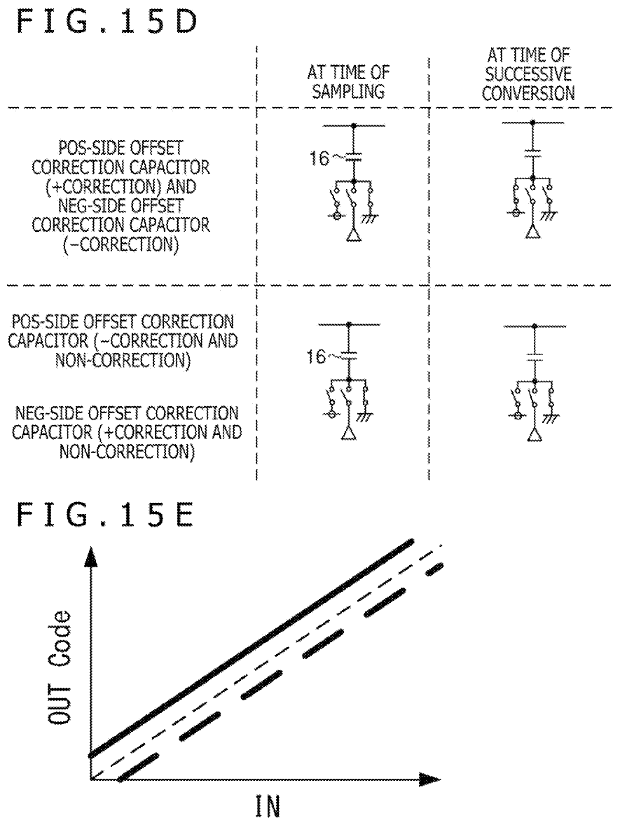

Alternatively, the capacitive DAC 1 may include a positive (POS)-side DAC and a negative (NEG)-side DAC (differential type: see FIG. 15B described later). In this case, a POS-side analog input voltage POSIN is input into the POS-side DAC, and a NEG-side analog input voltage NEGIN is input into the NEG-side DAC. Further, the output of the POS-side DAC is input into the first input terminal of the comparator 2, and the output of the NEG-side DAC is input into the second input terminal of the comparator 2. In this configuration, AD conversion is performed on the difference between the POS-side analog input voltage POSIN and the NEG-side analog input voltage NEGIN.

An AD conversion operation in the ADC 10 is specifically described. The analog input voltage IN is first sampled by the capacitive DAC 1. Subsequently, the control logic unit 3 sets the initial digital signal DG. Here, “1” is set to the most significant bit (MSB), and “0” to the other bits.

Then, the comparator 2 outputs the comparator output CMPOUT. The control logic unit 3 determines the most significant bit to “1” or “0” according to the comparator output CMPOUT. Subsequently, the control logic unit 3 sets “1” to the second highest order bit (hereinafter referred to as a “high-order bit”) following the most significant bit and sets “0” to the bits lower than the high-order bit.

Then, the comparator 2 outputs the comparator output CMPOUT. The control logic unit 3 determines the above-described high-order bit as “1” or “0” according to the comparator output CMPOUT. Further, the control logic unit 3 sets “1” to the next highest order bit following the above-described high-order bit and sets “0” to the bits lower than this bit.

The same operation is repeated thereafter. In this way, the ADC 10 performs bit-by-bit successive approximation to determine the value of each bit and generate the digital output OUT.

### Configuration of Capacitive DAC

FIG. 2 is a diagram illustrating a configuration of a capacitive DAC 1x according to a first comparative example. The capacitive DAC 1x is, as an example, a DAC corresponding to 16 bits and includes bit capacitors 11 each corresponding to an individual bit. “15” denoted in FIG. 2 is the most significant bit among the 16 bits while “0” denoted in FIG. 2 is the least significant bit among the 16 bits.

In the example illustrated in FIG. 2, the bit capacitors 11 for the low-order 6 bits (0 to 5) are connected in parallel to the same line Ln1. The bit capacitors 11 for the high-order 10 bits (6 to 15) are connected in parallel to the same line Ln2. The line Ln1 and the line Ln2 are connected to each other by a connection capacitor 12.

The capacitances of the bit capacitors 11 sequentially become larger from the least significant bit “0” to the 6th bit “5” by a factor of 2 times a unit capacitance C. The capacitance of the bit capacitor 11 for the least significant bit “0” is 1 time the unit capacitance C. That is, the capacitance for the least significant bit=C, and the capacitance for the 6th bit=32C. Further, the capacitances of the bit capacitors 11 sequentially become larger from the 7th bit “6” from the least significant bit to the most significant bit “15” by a factor of 2 times the unit capacitance C. The capacitance of the bit capacitor for the 7th bit “6” from the least significant bit is 1 time the unit capacitance C. That is, the capacitance for the 7th bit=10, and the capacitance for the most significant bit=512C.

The capacitance of the connection capacitor 12 is (64/63)C. The analog output voltage VA is generated through the line Ln2. Providing the connection capacitor 12 prevents the capacitance of the most significant bit from increasing.

The capacitive DAC 1x includes an adjustment capacitor 13. One terminal of the adjustment capacitor 13 is connected to the line Ln1 while the other terminal of the adjustment capacitor 13 is connected to an application terminal of the ground potential. The adjustment capacitor 13 adjusts the effect on the analog output voltage VA such that the effect at the 6th bit “5” from the least significant bit is half the effect at the 7th bit “6” from the least significant bit. The capacitance of the adjustment capacitor 13 is 10.

A first terminal of the bit capacitor 11 for each bit is connected to the line Ln1 or Ln2. The analog input voltage IN, a power supply voltage Vcc, or the ground potential can be selectively applied to a second terminal of the bit capacitor 11 for each bit. The control of this voltage application is performed by the control logic unit 3.

At the time of sampling, the analog input voltage IN is applied to the second terminals of the bit capacitors 11 for all bits. At this time, a fixed voltage (e.g., the ground potential) is applied to the line Ln2. After that, the application of the above-described analog input voltage IN and fixed voltage is released, and the successive approximation operation starts. In the successive approximation operation, the power supply voltage Vcc or the ground potential is applied to the second terminal of the bit capacitor 11 for each bit according to each bit of the digital signal DG set by the control logic unit 3. Specifically, when a bit of the digital signal DG is “1” (high level), the power supply voltage Vcc is applied. When a bit of the digital signal DG is “0” (low level), the ground potential is applied.

FIG. 3 is a diagram illustrating a configuration of a capacitive DAC 1y according to a second comparative example, which is an example improved from the first comparative example. The capacitive DAC 1y includes two connection capacitors 121 and 122. A line Ln11 and a line Ln13 are connected to each other by the connection capacitor 121, while a line Ln12 and the line Ln13 are connected to each other by the connection capacitor 122.

The bit capacitors 11 for the low-order 4 bits (0 to 3) are connected in parallel to the line Ln11. The bit capacitors 11 for the middle-order 4 bits (4 to 7) are connected in parallel to the line Ln12. The bit capacitors 11 for the high-order 8 bits (8 to 15) are connected in parallel to the line Ln13.

The capacitances of the bit capacitors 11 sequentially become larger from the least significant bit “0” to the 4th bit “3” by a factor of 2 times the unit capacitance C. The capacitance of the bit capacitor 11 for the least significant bit “0” is 2 times the unit capacitance C. That is, the capacitance for the least significant bit=2C, and the capacitance for the 4th bit=16C. Further, the capacitances of the bit capacitors 11 sequentially become larger from the 5th bit “4” from the least significant bit to the 8th bit “7” by a factor of 2 times the unit capacitance C. The capacitance of the bit capacitor 11 for the 5th bit “4” from the least significant bit is 1 time the unit capacitance C. That is, the capacitance for the 5th bit=10, and the capacitance for the 8th bit=8C. Further, the capacitances of the bit capacitors 11 sequentially become larger from the 9th bit “8” from the least significant bit to the most significant bit “15” by a factor of 2 times the unit capacitance C. The capacitance of the bit capacitor 11 for the 9th bit “8” from the least significant bit is 4 times the unit capacitance C. That is, the capacitance for the 9th bit=4C, and the capacitance for the most significant bit=512C.

The capacitance of the connection capacitor 121 is 2C, and the capacitance of the connection capacitor 122 is 12C. In this way, in the second comparative example, the capacitances of the connection capacitors 121 and 122 can be configured without the need to use a capacitance that is not an integer multiple of the unit capacitance like the connection capacitor 12 (=(64/63)C) in the first comparative example. According to the second comparative example, the capacitances (4C and 8C) of the bit capacitors 11 for the 7th bit “6” and the 8th bit “7” from the least significant bit are larger than the corresponding capacitances (1C and 2C) in the first comparative example. This improves the matching accuracy of the capacitance.

The capacitive DAC 1y includes adjustment capacitors 131 and 132 in such a manner as to correspond to the provision of the connection capacitors 121 and 122. The capacitance of the adjustment capacitor 131 is 246C, and the capacitance of the adjustment capacitor 132 is 21C. The adjustment capacitor 132 adjusts the effect on the analog output voltage VA such that the effect at the 8th bit “7” from the least significant bit is half the effect at the 9th bit “8” from the least significant bit. The adjustment capacitor 131 adjusts the effect on the analog output voltage VA such that the effect at the 4th bit “3” from the least significant bit is half the effect at the 5th bit “4” from the least significant bit.

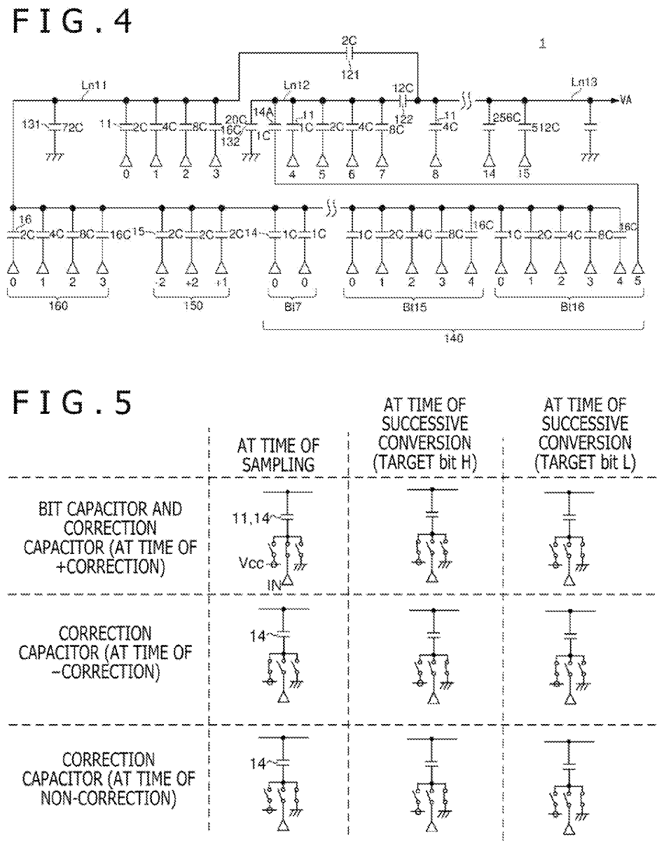

FIG. 4 is a diagram illustrating an example of a configuration of the capacitive DAC 1 according to the first embodiment of the present disclosure. The configuration illustrated in FIG. 4 is a configuration improved from the second comparative example.

In the configuration illustrated in FIG. 4, a portion of the capacitance (=246C) of the adjustment capacitor 131 in the second comparative example is allocated to the capacitance of each correction capacitor 14 in a capacitance correction unit 140, the capacitance of each search capacitor 15 in a re-search unit 150, and the capacitance of each offset adjustment capacitor 16 in an offset correction unit 160, while the remaining capacitor is allocated to the capacitance (=72C) of the adjustment capacitor 131.

Each correction capacitor 14 in the capacitance correction unit 140 is a capacitor for correcting the capacitance against the capacitance variation of the bit capacitor 11 for each bit and is connected in parallel to the line Ln11. The correction capacitor 14 is provided for each bit capacitor 11 for a correction target bit. In the example illustrated in FIG. 4, a bit correction unit Bt16 is provided in such a manner as to correspond to the bit capacitor 11 (512C) for the most significant bit “15.” The bit correction unit Bt16 includes the correction capacitors 14 each corresponding to a corresponding one of the correction bits “0” to “4.” The capacitances of the correction capacitors 14 sequentially become larger from the correction bit “0” to “4” by a factor of 2 times the unit capacitance C. The capacitance of the correction capacitor 14 for the correction bit “0” is 1 time the unit capacitance C. That is, the capacitance for the correction bit “0”=10, and the capacitance for the correction bit “4”=16C.

A correction capacitor 14A corresponding to the most significant correction bit “5” in the bit correction unit Bt16 is connected to the line Ln12. Of the capacitance (=21C) of the adjustment capacitor 132 in the second comparative example, 1C is allocated to the correction capacitor 14A, and the remaining 20C is allocated to the adjustment capacitor 132. The capacitance=10 of the correction capacitor 14A corresponds to the capacitance=32C of the correction capacitor 14 connected to the line Ln11.

In the example illustrated in FIG. 4, a bit correction unit Bt15 is provided in such a manner as to correspond to the bit capacitor 11 (256C) for the second most significant bit “14.” The bit correction unit Bt15 includes the correction capacitors 14 each corresponding to a corresponding one of the correction bits “0” to “4.” The capacitances of the correction capacitors 14 sequentially become larger from the correction bit “0” to “4” by a factor of 2 times the unit capacitance C. The capacitance of the correction capacitor 14 for the correction bit “0” is 1 time the unit capacitance C. That is, the capacitance for the correction bit “0”=10, and the capacitance for the correction bit “4”=16C.

In the example of FIG. 4, each of the bit correction units Bt16 to Bt7 is provided for a corresponding one of the bit capacitors 11 from the bit “15” to the bit “6.” The lower the bit becomes from the bit “15” to the bit “6,” the narrower the correction range of the correction capacitors 14 and 14A. For example, the correction range in the bit correction unit Bt16 corresponding to the bit “15” is 1C+2C+4C+8C+16C+32C, which is the sum of the capacitances of the correction capacitors.

The correction capacitors may be connected to the line Ln13. It is noted that the re-search unit 150 and the offset correction unit 160 are described later.

### Capacitance Correction Control

FIG. 5 is a diagram illustrating a capacitance correction control method. Specifically, FIG. 5 is a diagram illustrating a voltage application control method for the bit capacitors 11 and the correction capacitors 14 (including 14A). The voltage application control is performed by the control logic unit 3.

As illustrated in FIG. 5, at the time of sampling, the analog input voltage IN is applied to the bit capacitor 11 for the normal comparison bit (bit of the bit capacitor 11) and to the correction capacitor 14 corresponding to the correction bit at the time of the + correction. The + correction is to correct the capacitance decrease (increase the capacitance) caused by the capacitance variation of the bit capacitor 11 corresponding to the normal comparison bit that is the correction target.

At the time of successive approximation, when the target bit is set to “1” (high level) by the setting of the digital signal DG, the power supply voltage Vcc is applied to the bit capacitor 11 for the normal comparison bit (bit of the bit capacitor 11) and the correction capacitor 14 corresponding to the correction bit at the time of + correction, and when the target bit is set to “0” (low level), the ground potential is applied thereto. The normal comparison bit and the corresponding correction bit are set to the same logic.

Further, both at the time of sampling and at the time of successive approximation, the ground potential is constantly applied to the correction capacitor 14 corresponding to the correction bit at the time of non-correction. The power supply voltage Vcc may be constantly applied thereto, as indicated by a single-dotted frame of FIG. 5. The correction bit at the time of non-correction is a correction bit that is not used for correction. For example, in the same bit correction unit (e.g., Bt16), a correction bit that is used for correction and a correction bit that is not used for correction may exist.

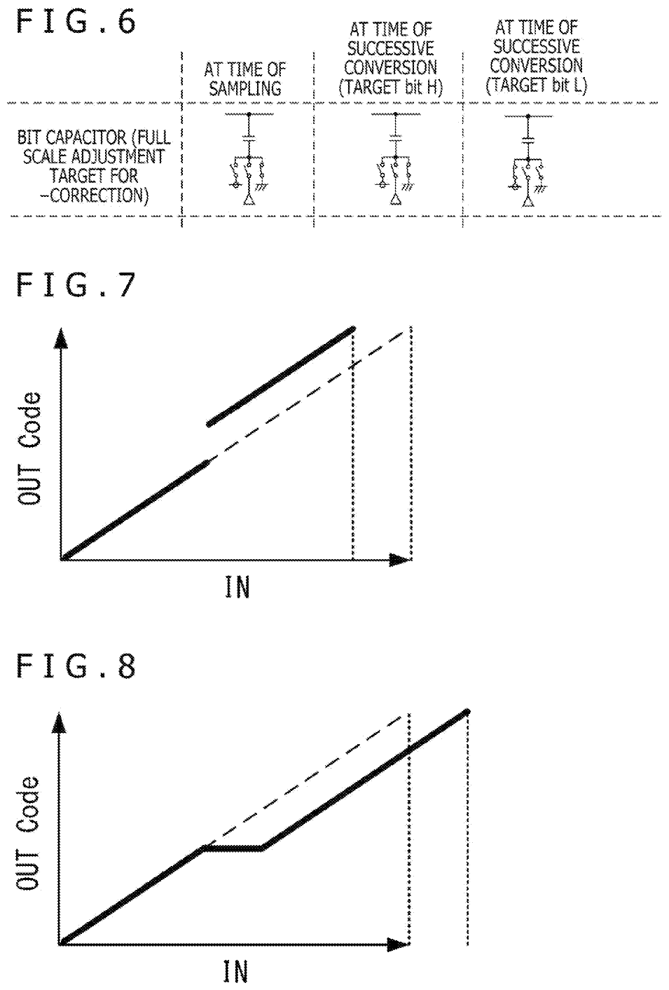

FIG. 7 is a diagram illustrating, as an example, a correspondence relation between the analog input voltage IN and the code of the digital output OUT when the bit capacitor 11 (=512C) at the most significant bit “15” decreases in capacitance due to capacitance variation. In this case, as indicated by a thick solid line of FIG. 7, the code of the digital output OUT shifts in the middle of the analog input voltage IN, and the linearity of AD conversion decreases. Therefore, performing the + correction according to the present embodiment can improve the linearity as indicated by a dashed line of FIG. 7. In this case, the analog input voltage IN is applied to the correction capacitor 14 corresponding to the correction bit that is the correction target, at the time of sampling, so that AD conversion corresponding to the full scale of the analog input voltage IN can be performed.

As illustrated in FIG. 5, at the time of sampling, the power supply voltage Vcc is applied to the correction capacitor 14 corresponding to the correction bit at the time of − correction. The − correction is to correct the capacitance increase (decrease the capacitance) caused by the capacitance variation of the bit capacitor 11 corresponding to the normal comparison bit that is the correction target.

At the time of successive approximation, when the target bit is set to “1” (high level) by the setting of the digital signal DG, the ground potential is applied to the correction capacitor 14 corresponding to the correction bit at the time of − correction, and when the target bit is set to “0” (low level), the power supply voltage Vcc is applied thereto. In other words, the correction bit at the time of − correction is set to the logic opposite to that of the normal comparison bit.

Further, as illustrated in FIG. 6, at the time of sampling, the ground potential is applied to the bit capacitor 11 for the normal comparison bit with the same capacitance corresponding to the correction bit at the time of − correction (e.g., the normal comparison bit “3” corresponding to the correction bit “4” (=16C) in the bit correction unit Bt16). At the time of successive approximation, when the target bit is set to “1” (high level) by the setting of the digital signal DG, the ground potential is applied to this bit capacitor 11, and when the target bit is set to “0” (low level), the power supply voltage Vcc is applied thereto.

FIG. 8 is a diagram illustrating, as an example, a correspondence relation between the analog input voltage IN and the code of the digital output OUT when the bit capacitor 11 (=512C) for the most significant bit “15” increases in capacitance due to capacitance variation. In this case, as indicated by a thick solid line of FIG. 8, the code of the digital output OUT does not change in the middle of the analog input voltage IN, and the linearity of AD conversion decreases. Therefore, performing the − correction according to the present embodiment can improve the linearity as indicated by a dashed line of FIG. 8. In order to decrease the electric charge excessively charged by sampling and holding, the analog input voltage IN is, at the time of sampling, not applied to the bit capacitor 11 for the normal comparison bit with the same capacitance corresponding to the correction bit at the time of − correction, as described above. Accordingly, AD conversion corresponding to the full scale of the analog input voltage IN can be performed.

### Adjustment of Connection Capacitor

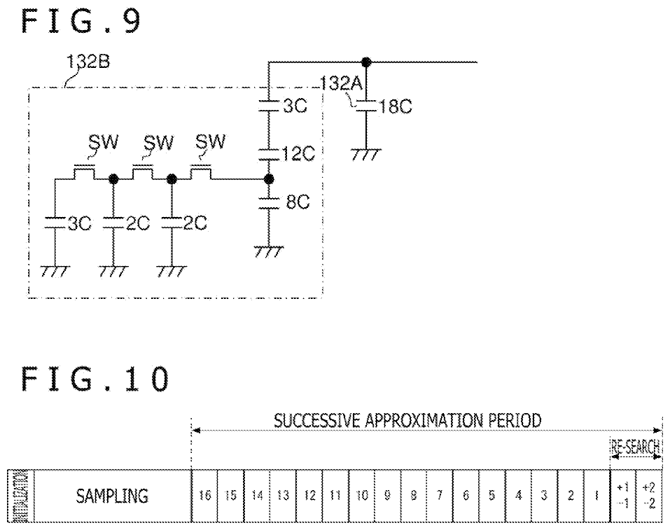

FIG. 9 illustrates an example of a configuration for adjusting the connection capacitor 122 (=12C) illustrated in FIG. 4. In the configuration illustrated in FIG. 9, the adjustment capacitor 132 (=20C) illustrated in FIG. 4 is divided into a capacitor 132A with 18C and a capacitor 132B with 2C. In the capacitor 132B with 2C, capacitors with 3C, 12C, and 8C are connected in series, and capacitors with 8C, 2C, 2C, and 3C are connected in parallel via switches SW. The capacitance of the capacitor 132B can be adjusted by turning the switches SW on and off. This is equivalent to adjusting the connection capacitor 122.

### Re-Search Function

As described earlier, the re-search unit 150 is provided in the capacitive DAC 1 illustrated in FIG. 4, and a re-search function is described here. FIG. 10 is a diagram illustrating a sequence of the AD conversion process according to the present embodiment. As illustrated in FIG. 10, after initialization, sampling is performed, followed by a successive approximation period.

In the successive approximation period, successive conversion is performed from the most significant bit “16” to the least significant bit “1,” after which a re-search period is provided. In the case of a form without re-search, the process ends with the successive conversion at the least significant bit. However, there has been a possibility that shortening the conversion time at each bit to shorten the processing time may deteriorate the performance of differential non-linearity (DNL). Therefore, in the present embodiment, the re-search function is provided such that, even when the conversion time at each bit is shortened, the performance of DNL improves.

For example, assume a case where the initialization time is 20 ns and the sampling time is 140 ns and no re-search is performed. In this case, if each conversion time from the most significant bit to the least significant bit is increased to 36 ns to suppress the performance deterioration of DNL, the AD conversion processing time becomes 20+140+36×16=736 ns. By contrast, when re-search is performed as in the present embodiment, each conversion time from the most significant bit to the second least significant bit “2” is shortened to 24 ns, and the conversion time at the least significant bit and the conversion time at the time of re-search (+1LSB, +2LSB or −1LSB, −2LSB to be described later) are set to slightly longer time, 36 ns. In this case, the AD conversion processing time is 20+140+24×15+36×3=628 ns. Therefore, the AD conversion processing time can be shortened.

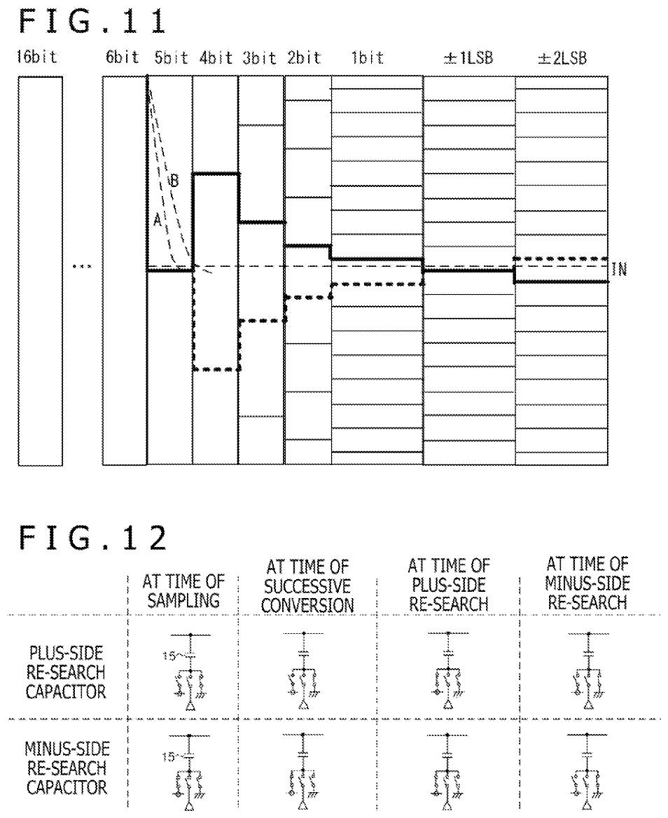

FIG. 11 is a diagram illustrating an example of the transition of the DA conversion output of the capacitive DAC 1 in the successive conversion at each bit (16 to 1) and re-search (±1LSB, ±2LSB). The analog input voltage IN is also illustrated in FIG. 11.

In FIG. 11, a dashed line A indicates an actual waveform of the DA conversion output in the successive conversion at the 5th bit from the least significant bit. This indicates that the target tracking performance of the DA conversion output is good and the DA conversion output has reached the target within the conversion time. The transition of the DA conversion output in this case is indicated by a thick solid line. In this case, the analog input voltage IN is lower than the DA conversion output at the least significant bit (1st bit), and the least significant bit is determined as “0” (low level). In this case, further comparison is performed with the DA conversion output as −1LSB and −2LSB (re-search).

In FIG. 11, a dashed line B indicates an actual waveform of the DA conversion output in the successive conversion at the 5th bit from the least significant bit. This indicates that the target tracking performance of the DA conversion output is lower than the dashed line A and the DA conversion output has not been able to reach the target within the conversion time. The transition of the DA conversion output in this case is indicated by a thick dashed line. In this case, the analog input voltage IN is higher than the DA conversion output at the least significant bit (1st bit), and the least significant bit is determined as “1” (high level). In this case, further comparison is performed with the DA conversion output as +1LSB and +2LSB (re-search).

As illustrated in FIG. 4, the capacitive DAC 1 according to the present embodiment includes the re-search unit 150. The re-search unit 150 includes the search capacitor 15 for +1LSB search, the search capacitor 15 for +2LSB search, and the search capacitor 15 for −2LSB search. Each search capacitor 15 is connected in parallel to the line Ln11. The capacitance of each search capacitor 15 is 2C which is the same as the capacitance of the bit capacitor 11 for the least significant bit. Accordingly, the re-search step is 1LSB. The reason why no capacitor is provided for −1LSB search is that the re-search step automatically becomes −1LSB when the least significant bit is at the low level.

FIG. 12 is a diagram illustrating the voltage application control method for each of the bit capacitors 11 for the normal comparison bits, the search capacitors 15 for the re-search plus-side bits (+1LSB, +2LSB), and the search capacitor 15 for the re-search minus-side bit (−2LSB).

The ground potential or the power supply voltage Vcc is applied to the bit capacitor 11 for the normal comparison bit according to the logic that has already been determined at the time of the plus-side re-search and the minus-side re-search. The ground potential is applied to the search capacitor 15 for the re-search plus-side bit at the time of sampling and successive approximation. The power supply voltage Vcc is applied thereto at the time of the plus-side re-search, and the ground potential is applied thereto at the time of the minus-side re-search. The power supply voltage Vcc is applied to the search capacitor 15 for the re-search minus-side bit at the time of sampling and successive approximation. The power supply voltage Vcc is applied thereto at the time of the plus-side re-search. The ground potential is applied thereto at the time of the minus-side re-search.

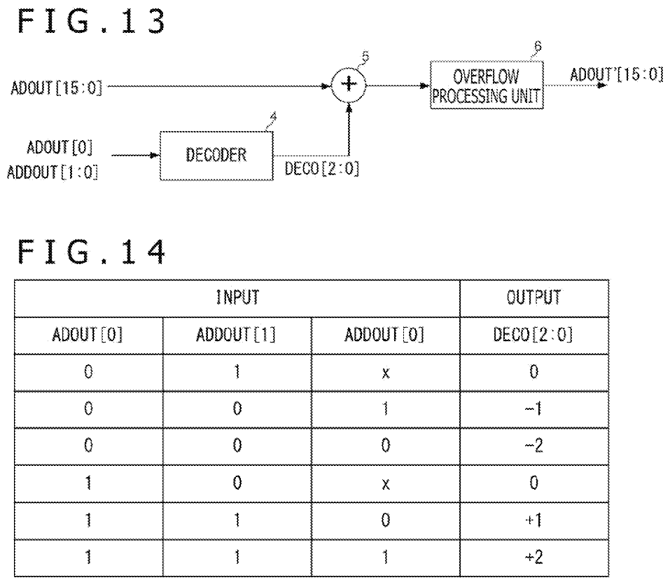

In the case of having the re-search function, the ADC according to the present embodiment has a configuration illustrated in FIG. 13 in addition to the configuration illustrated in FIG. 1. As illustrated in FIG. 13, a decoder 4, an addition unit 5, and an overflow processing unit 6 are provided.

ADOUT[15:0] indicated in FIG. 13 corresponds to the digital output OUT (16-bit code) output from the control logic unit 3 illustrated in FIG. 1 and is input into the addition unit 5. ADOUT[0] is the least significant bit data. ADDOUT[1:0] indicates the comparison result for each of +1LSB and +2LSB at the time of the plus-side re-search or the comparison result for each of −1LSB and −2LSB at the time of the minus-side re-search.

The decoder 4 converts ADOUT[0] and ADDOUT[1:0] into a decoder output DECO[2:0]. The addition unit 5 adds ADOUT[15:0] and the decoder output DECO[2:0] and outputs a final output ADOUT′[15:0] via the overflow processing unit 6. The overflow processing unit 6 limits the output of the addition unit 5 to the upper or lower limit when the output of the addition unit 5 exceeds the upper or lower limit.

FIG. 14 is a table indicating a conversion process in the decoder 4. ADDOUT[1]=1 indicates the case where the analog input voltage IN is higher than the DA conversion output at the time of the +1LSB or −1LSB re-search. ADDOUT[1]=0 indicates the case where the analog input voltage IN is lower than the DA conversion output at the time of the +1LSB or −1LSB re-search. ADDOUT[0]=1 indicates the case where the analog input voltage IN is higher than the DA conversion output at the time of the +2LSB or −2LSB re-search. ADDOUT[0]=0 indicates the case where the analog input voltage IN is lower than the DA conversion output at the time of +2LSB or −2LSB re-search.

FIG. 15A is a diagram illustrating a configuration of the control logic unit 3. The control logic unit 3 includes NAND circuits 31, D flip-flops 32, and NAND circuits 33 for a predetermined number of bits (16 bits herein). The NAND circuit 31, the D flip-flop 32, and the NAND circuit 33 are provided for each bit.

A clock CK16 is input into a first input terminal of the NAND circuit 31 for the most significant bit, while a logic inversion of a clock CK15 is input into a second input terminal of the NAND circuit 31. The comparator output CMPOUT of the comparator 2 is input into a D terminal of the D flip-flop 32 for the most significant bit, while the clock CK15 is input into a clock terminal of the D flip-flop 32. The output of the NAND circuit 31 is input into a first input terminal of the NAND circuit 33, while a logic inversion of the output of the D flip-flop 32 is input into a second input terminal of the NAND circuit 33. Depending on the output of the NAND circuit 33, the power supply voltage Vcc or the ground potential is applied to the bit capacitor 11.

The configurations of the NAND circuits 31, the D flip-flops 32, and the NAND circuits 33 for the bits lower than the most significant bit are the same as those described above. It is noted that ADOUT[15:0] is configured from the output of the NAND circuit 33 for each bit.

FIG. 15A illustrates waveforms of clocks CK16 to CK0, CKA1, and CKA2. The clocks CK16 to CKA2 are initially at the low level, and the clock CK16 rises to the high level first. After that, the output of the NAND circuit 33 for the most significant bit rises to the high level, and the power supply voltage Vcc is applied to the bit capacitor 11 for the most significant bit. At this time, the output of the NAND circuit 33 for each bit other than the most significant bit is at the low level, and the ground potential is applied to the bit capacitor 11 for each bit other than the most significant bit.

After that, when the clock CK15 rises to the high level, the comparator output CMPOUT is output from the D flip-flop 32, and the output of the NAND circuit 33 is determined according to the logic of the comparator output CMPOUT. Accordingly, the most significant bit is determined. At this time, the output of the NAND circuit 33 for the second most significant bit becomes the high level, and the power supply voltage Vcc is applied to the bit capacitor 11 for the second most significant bit.

After that, the logic for each bit is determined as the clocks CK14 to CK0 rise in sequence. In other words, ADOUT[15:0] is determined.

The control logic unit 3 includes an AND circuit 34, a D flip-flop 35, an AND circuit 36, a NAND circuit 37, and a D flip-flop 38 in such a manner as to correspond to the re-search function.

The clock CK0 is input into a first input terminal of the AND circuit 34, and the output of the D flip-flop 32 for the least significant bit is input into a second input terminal of the AND circuit 34. The power supply voltage Vcc or the ground potential is applied to the search capacitor 15 for +1LSB re-search, depending on the output of the AND circuit 34. The comparator output CMPOUT is input into a D terminal of the D flip-flop 35, and the clock CKA1 is input into a clock terminal of the D flip-flop 35. ADDOUT[1] is output from the D flip-flop 35.

The clock CKA1 is input into a first input terminal of the AND circuit 36, and the output of the D flip-flop 32 for the least significant bit is input into a second input terminal of the AND circuit 36. The power supply voltage Vcc or the ground potential is applied to the search capacitor 15 for +2LSB re-search, depending on the output of the AND circuit 36. The clock CKA1 is input into a first input terminal of the NAND circuit 37, and the logic inversion of the output of the D flip-flop 32 for the least significant bit is input into a second input terminal of the NAND circuit 37. The power supply voltage Vcc or the ground potential is applied to the search capacitor 15 for −2LSB re-search, depending on the output of the NAND circuit 37.

The comparator output CMPOUT is input into a D terminal of the D flip-flop 38, and the clock CKA2 is input into a clock terminal of the D flip-flop 38. ADDOUT[0] is output from the D flip-flop 38.

In response to the rising of the clock CK0, the comparator output CMPOUT is output from the D flip-flop 32 for the least significant bit. When the output of the D flip-flop 32 is at the low level, that is, when the least significant bit=“0,” the AND circuits 34 and 36 are disabled, and the NAND circuit 37 is enabled. When the least significant bit=“0,” the DA conversion output automatically becomes −1LSB. Subsequently, in response to the rising of the clock CKA1, the comparator output CMPOUT is output from the D flip-flop 35 as ADDOUT[1]. At this time, the output of the NAND circuit 37 becomes the low level, and the DA conversion output is −2LSB. After that, in response to the rising of the clock CKA2, the comparator output CMPOUT is output from the D flip-flop 38 as ADDOUT[0]. In this way, when the least significant bit=“0” (low level), −1LSB and −2LSB re-search are performed.

When the clock CK0 rises and the output of the D flip-flop 32 for the least significant bit is at the high level, that is, the least significant bit=“1,” the AND circuits 34 and 36 are enabled, and the NAND circuit 37 is disabled. At this time, the output of the AND circuit 34 becomes the high level, and the DA conversion output is +1LSB. After that, in response to the rising of the clock CKA1, the comparator output CMPOUT is output from the D flip-flop 35 as ADDOUT[1]. At this time, the output of the AND circuit 36 becomes the high level, and the DA conversion output is +2LSB. Subsequently, in response to the rising of the clock CKA2, the comparator output CMPOUT is output from the D flip-flop 38 as ADDOUT[0]. In this way, when the least significant bit=“1” (high level), +1LSB and +2LSB re-search are performed.

### Offset Correction

As described earlier, the capacitive DAC 1 illustrated in FIG. 4 includes the offset correction unit 160, and an offset correction function is described here. As illustrated in the example of FIG. 15E, offset is performed when the relation between the analog input voltage IN and the code of the digital output OUT shifts from a dashed line to a thick solid line or a thick dashed line, that is, the plus-side or minus-side.

In the example illustrated in FIG. 4, the offset correction unit 160 includes offset correction capacitors 16, which are connected in parallel to the line Ln11. In the example illustrated in FIG. 4, the capacitances of the offset correction capacitors 16 are 2, 4, 8, and 16 times the unit capacitance, respectively (i.e., 2C, 4C, 8C, and 16C).

As illustrated in FIG. 15B, the capacitive DAC 1 includes a POS-side DAC 1A and a NEG-side DAC 1B. The POS-side analog input voltage POSIN is input into the POS-side DAC 1A, and the NEG-side analog input voltage NEGIN is input into the NEG-side DAC 1B. A POS-side analog output voltage POSVA output from the POS-side DAC 1A is input into the first input terminal of the comparator 2, and a NEG-side analog output voltage NEGVA output from the NEG-side DAC 1B is input into the second terminal of the comparator 2.

FIG. 15C is a diagram illustrating a first example of an offset correction control method. Specifically, FIG. 15C illustrates a voltage application control method for the offset correction capacitors 16. This voltage application control is performed by the control logic unit 3. In the method illustrated in FIG. 15C, + correction or − correction is performed by controlling the voltage application to the POS-side offset correction capacitor 16. The + correction is to correct the minus-side offset to the plus-side offset. The − correction is to correct the plus-side offset to the minus-side offset.

In the method illustrated in FIG. 15C, at the time of + correction, the ground potential is applied to the POS-side offset correction capacitor 16 when sampling is performed, and the power supply voltage is applied thereto when successive approximation is performed. At the time of the − correction, the power supply voltage is applied to the POS-side offset correction capacitor 16 when sampling is performed, and the ground potential is applied thereto when successive approximation is performed.

A fixed ground potential is applied to the NEG-side offset correction capacitor 16 and the POS-side offset correction capacitor 16 at the time of non-correction when sampling or successive conversion is performed. It is noted that a fixed power supply voltage may be applied.

FIG. 15D is a diagram illustrating a second example of the offset correction control method. In the method illustrated in FIG. 15D, + correction or − correction is performed by controlling the voltage application of either the POS-side offset correction capacitor 16 or the NEG-side offset correction capacitor 16.

In the method illustrated in FIG. 15D, at the time of + correction, the ground potential is applied to the POS-side offset correction capacitor 16 when sampling is performed, and the power supply voltage is applied thereto when successive approximation is performed. At the time of − correction, the ground potential is applied to the NEG-side offset correction capacitor 16 when sampling is performed, and the power supply voltage is applied thereto when successive approximation is performed.

A fixed ground potential is applied to the POS-side offset correction capacitor 16 at the time of − correction or non-correction when sampling or successive conversion is performed. It is noted that a fixed power supply voltage may be applied.

A fixed ground potential is applied to the NEG-side offset correction capacitor 16 at the time of + correction or non-correction when sampling or successive conversion is performed. It is noted that a fixed power supply voltage may be applied.

### 2. Second Embodiment

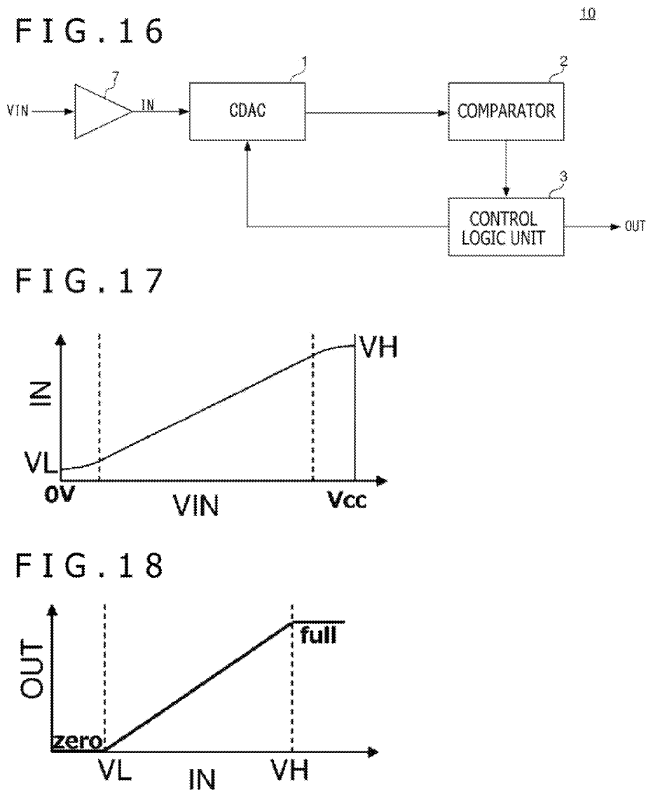

As illustrated in FIG. 16, an output terminal of an operational amplifier 7 may be connected to the input terminal of the successive-approximation ADC 10. In this case, an input voltage VIN input into the operational amplifier 7 is input into the ADC 10 as the analog input voltage IN. However, the output of the operational amplifier 7 may not be able to be output from the ground potential (0 V) to the power supply voltage Vcc. As illustrated in FIG. 17, for example, the output range is limited to, for example, from a lower limit voltage VL=ground potential+0.5 V to an upper limit voltage VH=power supply voltage Vcc−0.5 V.

In this case, if the analog input voltage IN=0V is converted into zero code (all bits are “0”) of the digital output OUT and the analog input voltage IN=Vcc is converted into full code (all bits are “1”) of the digital output OUT through AD conversion performed by the ADC 10, an unusable code is generated and the resolution decreases. Therefore, it is more efficient to narrow the AD conversion range (dynamic (D) range) such that IN=0.5 V is converted into zero code and IN=Vcc−V is converted into full code.

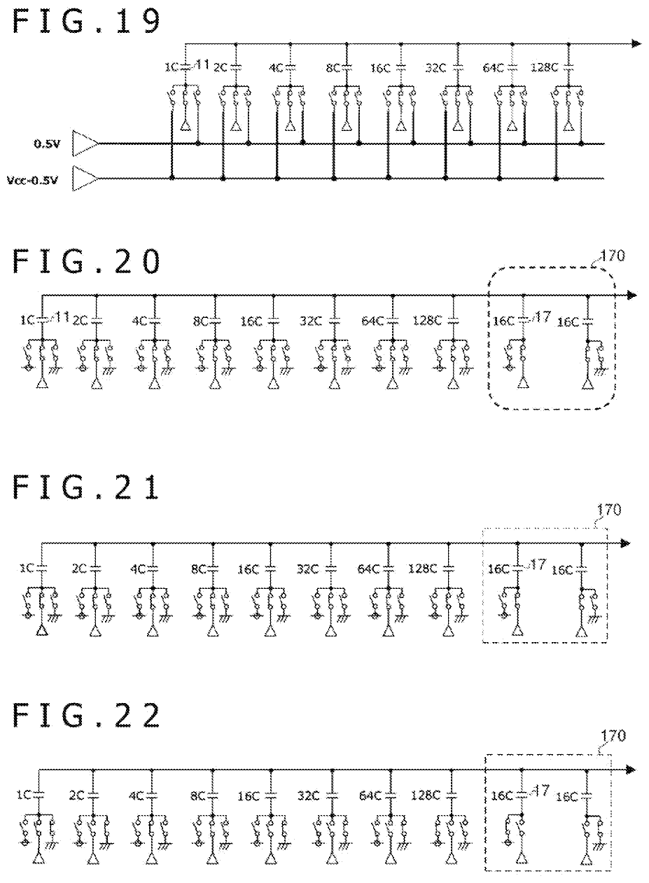

Therefore, it is conceivable to configure the capacitive DAC 1 as illustrated in FIG. 19, for example. The capacitive DAC 1 illustrated in FIG. 19 is an 8-bit DAC as an example and includes the bit capacitor 11 for each bit. In addition to the analog input voltage IN, the ground potential+V or Vcc−0.5 V can be selectively applied to each of the bit capacitors 11. This configuration can narrow the D-range, as illustrated in FIG. 18. However, this configuration requires the reference voltages of 0.5 V and Vcc−0.5 V, in addition to the ground potential and the power supply voltage Vcc.

Therefore, a second embodiment of the present disclosure employs the capacitive DAC 1 with the configuration illustrated in FIG. 20. The capacitive DAC 1 illustrated in FIG. 20 is an 8-bit DAC as an example and includes the bit capacitor 11 for each bit. In addition to the analog input voltage IN, the ground potential or the power supply voltage Vcc can be selectively applied to each of the bit capacitors 11.

Moreover, the capacitive DAC 1 illustrated in FIG. 20 includes a D-range adjustment unit 170. The D-range adjustment unit 170 includes two D-range capacitors 17 for adjusting the D-range. The analog input voltage IN or the power supply voltage Vcc can be selectively applied to one of the D-range capacitors 17, while the analog input voltage IN or the ground potential can be selectively applied to the other D-range capacitor 17.

FIG. 21 illustrates the state at the time of sampling in the capacitive DAC 1 according to the present embodiment. When sampling is performed, the analog input voltage IN is applied to all the bit capacitors 11 while the analog input voltage IN is applied to both the D-range capacitors 17.

FIG. 22 illustrates an example of the state at the time of successive approximation in the capacitive DAC 1 according to the present embodiment. When successive approximation is performed, the power supply voltage Vcc or the ground potential is applied to each bit capacitor 11, and the power supply voltage Vcc is applied to one of the D-range capacitors 17 while the ground potential is applied to the other D-range capacitor 17.

This configuration can narrow the D-range without changing the midpoint code of the digital output OUT, if the capacitances of the two D-range capacitors 17 are the same (16C in FIG. 20). It is noted that the capacitances of the two D-range capacitors 17 may be different from each other. Further, when successive approximation is performed, the power supply voltage Vcc or the ground potential may be applied to both the D-range capacitors 17.

In this way, the capacitive DAC 1 according to the present embodiment can narrow the D-range without the need for the reference voltages such as 0.5 V or Vcc−0.5 V as described above.

### 3. Third Embodiment

FIG. 23 is a diagram illustrating a configuration of the ADC 10 according to a third embodiment of the present disclosure. The ADC 10 according to the present embodiment includes a low-bit ADC 8, in addition to the capacitive DAC 1, the comparator 2, and the control logic unit 3. The low-bit ADC 8 outputs a lower number of bits (3 bits as an example here) than the number of bits of the digital output OUT of the ADC 10.

The low-bit ADC 8 compares the analog input voltage IN with each of a plurality of voltages divided from a reference voltage and converts the result of the comparison into digital output signals FLADO and FLADOD.

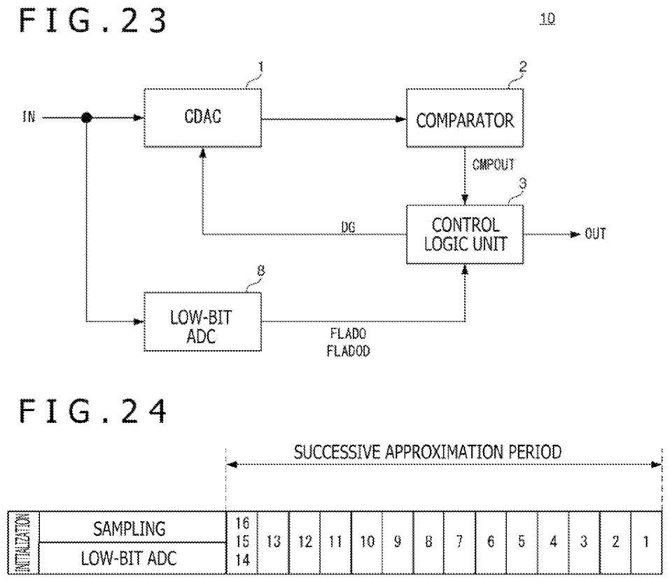

FIG. 24 is a diagram illustrating a sequence of the AD conversion process according to the present embodiment. The example illustrated in FIG. 24 indicates the case of 16-bit AD conversion. As illustrated in FIG. 24, after initialization, AD conversion is performed by the low-bit ADC 8 in parallel with sampling performed by the capacitive DAC 1.

Both the digital output signals FLADO and FLADOD output from the low-bit ADC 8 are 3-bit data (FLADO[2:0], FLADOD[2:0]) in this example. The 3 bits correspond to the upper three bits (16, 15, 14) of the AD conversion. FLADOD is a value smaller than FLADO by 1 in decimal.

The control logic unit 3 sets the digital signal DG on the basis of the digital output signal FLADO. The comparator 2 compares the analog input voltage IN with the DA conversion output obtained by performing DA conversion on the digital signal DG by the capacitive DAC 1. On the basis of the comparator output CMPOUT of the comparator 2, the control logic unit 3 selects one of FLADOD and FLADO to determine the logic of the upper three bits (16, 15, 14).

After that, the process of setting the digital signal DG and determining the logic of each bit on the basis of the comparator output CMPOUT is repeated from the 13th bit to the least significant bit (13 to 1). The conversion time taken for successive approximation in the upper three bits and the 13th bit is longer than the conversion time for the 12th and following bits because the voltage change of the DA conversion output by the capacitive DAC 1 is large.

In the case of a configuration in which no low-bit ADC is provided, when each conversion time from the 16th bit to the 13th bit is set to 36 ns, which is longer than each conversion time, 24 ns, from the 12th and following bits, the AD conversion processing time is 20+140+36×4+24×12=592 ns. By contrast, in the case of the configuration of the present embodiment in which the low-bit ADC 8 is provided, the AD conversion processing time is 20+140+36×2+24×12=522 ns. Therefore, the AD conversion processing time can be reduced.

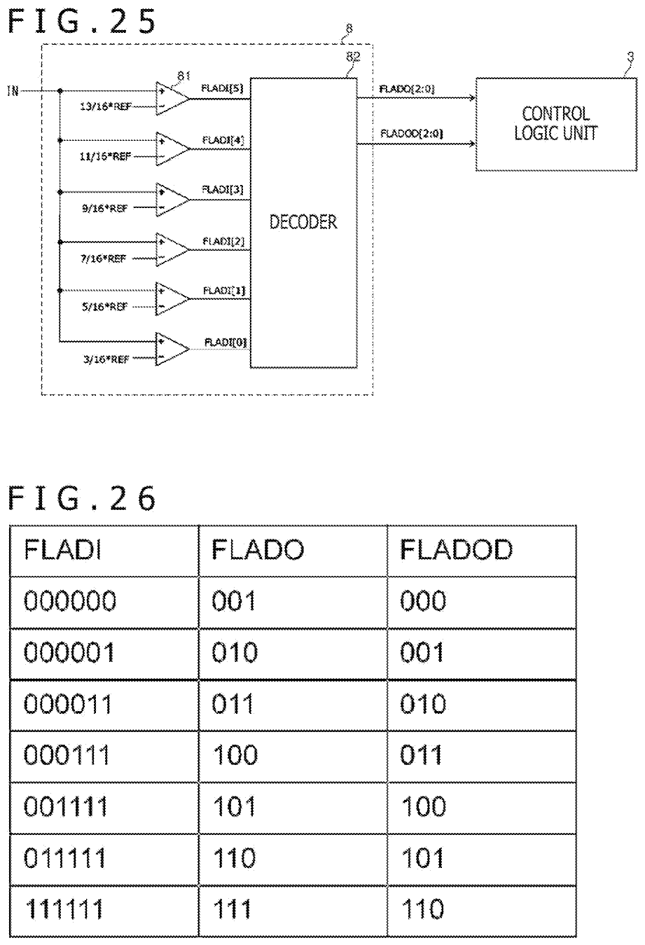

FIG. 25 is a diagram illustrating an example of a configuration of the low-bit ADC 8. The low-bit ADC 8 illustrated in FIG. 25 is what is generally called a flash ADC. The low-bit ADC 8 illustrated in FIG. 25 includes six comparators 81 and a decoder 82. The analog input voltage IN is input into a first input terminal of each of the comparators 81. Further, each of the six voltages ((13/16)×REF, (11/16)×REF, (9/16)×REF, (7/16)×REF, (5/16)×REF, and (3/16)×REF)) divided from the reference voltage REF is input into a second input terminal of a corresponding one of the comparators 81.

Each of comparison outputs FLADI[5] to FLADI[0] is output from a corresponding one of the comparators 81. The decoder 82 converts FLADI[5:0] into digital output signals FLADO[2:0] and FLADOD[2:0]. FIG. 26 illustrates a table for converting FLADI into FLADO and FLADOD.

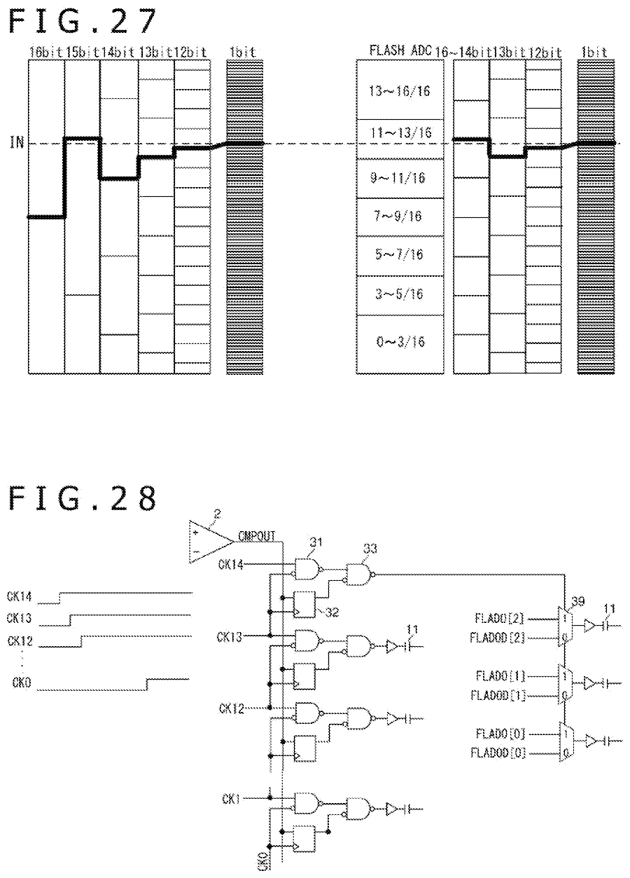

The left side of FIG. 27 illustrates an example of the transition of the DA conversion output of the capacitive DAC 1 at the time of successive approximation from the 16th bit (most significant bit) to the 1st bit when no low-bit ADC is provided. The analog input voltage IN is also illustrated in FIG. 27.

The right side of FIG. 27 illustrates an example of the transition of the DA conversion output of the capacitive DAC 1 at the time of successive approximation from the 16th bit (most significant bit) to the 1st bit in the present embodiment in which the low-bit ADC 8 is provided. The low-bit ADC 8 detects to which of the seven voltage ranges defined by the six voltages divided from the reference voltage REF the analog input voltage IN belongs. In the example illustrated in FIG. 27, the analog input voltage IN is detected as belonging to the voltage range of (11/16)×REF to (13/16)×REF, and the digital signal DG is set on the basis of FLADO (=110). In this case, as illustrated in FIG. 27, the analog input voltage IN is lower than the DA conversion output of the capacitive DAC 1 (16 to 14 bit in FIG. 27). Therefore, FLADOD is selected among FLADO and FLADOD, and the 16th to 14th bits are determined. Then, successive conversion is performed for the 13th and following bits.

In the case of the reference voltage REF=2.4 V, the comparator input range is ±1.2 V if no flash ADC is provided. By contrast, in the present embodiment in which the flash ADC is provided, the comparator input range is ±(1/16)×REF±0.05=±0.15±0.05=±0.2 V. 0.05 V is the accuracy of the flash ADC. This configuration can narrow the comparator input range.

FIG. 28 is a diagram illustrating an example of a configuration of the control logic unit 3 according to the present embodiment. The control logic unit 3 includes a combination of the NAND circuit 31, the D flip-flop 32, and the NAND circuit 33 for the upper three bits (16th bit to 14th bit) and for each of the 13th and following bits. The configurations of the NAND circuit 31, the D flip-flop 32, and the NAND circuit 33 are similar to those described with reference to FIG. 15A, and the clocks CK14 to CK0 are input into each of the above-described combinations.

The control logic unit 3 further includes selectors 39, each of which corresponds to a corresponding one of the upper three bits. The output of the NAND circuit 33 corresponding to the upper three bits is input into each of the selectors 39. FLADO[2] or FLADOD[2] is input into the selector 39 for the 16th bit. FLADO[1] or FLADOD[1] is input into the selector 39 for the 15th bit. FLADO[0] or FLADOD[0] is input into the selector 39 for the 14th bit. FLADO or FLADOD is selected and output depending on the output of the NAND circuit 33. Specifically, in the case of the output of the NAND circuit 33=1, FLADO is selected. In the case of the output of the NAND circuit 33=0, FLADOD is selected. A voltage is applied to the bit capacitors 11 of the capacitive DAC 1 according to the output of the selectors 39.

FIG. 28 also illustrates the waveforms of the clocks CK14 to CK0. The clocks CK14 to CK0 rise to the high level in this order. In response to the rising of the clock CK14, the output of the NAND circuit 33 becomes the high level, and FLADO is selected by the selectors 39. Subsequently, in response to the rising of the clock CK13, the comparator output CMPOUT is output from the D flip-flop 32. The selectors 39 make a selection according to the comparator output CMPOUT. The selection results of the selectors 39 are determined as the logics of the upper three bits. At this time, the output of the NAND circuit 33 for the 13th bit becomes the high level. After that, in response to the rising of the clock CK12, the comparator output CMPOUT is output from the D flip-flop 32, and the output of the NAND circuit 33 is determined as the logic for the 13th bit. After that, the logic for each bit is sequentially determined each time the clock rises.

### 4. Others

Various technical features disclosed in the present disclosure can be changed in various ways without departing from the scope of the above-described embodiments and the technical creation of the embodiments. That is, the embodiments are illustrative in all aspects and should not be construed as restrictive. The technical scope of the present disclosure is not limited to the embodiments, and it should be understood that all changes within the meaning and range of equivalents of the claims are included in the technical scope of the present disclosure.

### 5. Supplementary Note

As described above, for example, an analog-to-digital (AD) converter (10) according to an embodiment of the present disclosure includes a capacitive digital-to-analog converter (DAC) (1) into which an analog input voltage (IN) is input, a comparator (2) into which an output of the capacitive DAC is input, and a control logic unit (3) configured to control the capacitive DAC on the basis of an output of the comparator, in which the capacitive DAC includes first bit capacitors (11) connected in parallel to a first line (Ln13), second bit capacitors connected in parallel to at least one second line (Ln11, Ln12), a connection capacitor (121, 122) connecting the first line and the second line, an adjustment capacitor (131, 132) connected to the second line, and a bit correction unit (Bt16, etc.) corresponding to at least either the first bit capacitors or the second bit capacitors, the bit correction unit includes a correction capacitor (14) including a first terminal connected to at least one of the first line and the second line, and a voltage is able to be applied to a second terminal of the correction capacitor in conjunction with a first bit capacitor or second bit capacitor corresponding to the correction capacitor among the first bit capacitors and the second bit capacitors (first configuration: FIGS. 1 and 4).

In the first configuration described above, a voltage with the same logic as a logic for the first bit capacitor or second bit capacitor corresponding to the correction capacitor may be able to be applied to the second terminal of the correction capacitor in conjunction with the corresponding first bit capacitor or second bit capacitor (second configuration).

In the second configuration described above, when the analog input voltage is applied to the first bit capacitor or second bit capacitor corresponding to the correction capacitor, the analog input voltage may be able to be applied to the second terminal of the correction capacitor (third configuration).

In the first configuration described above, a voltage with a logic opposite to a logic for the first bit capacitor or second bit capacitor corresponding to the correction capacitor may be able to be applied to the second terminal of the correction capacitor in conjunction with the corresponding first bit capacitor or second bit capacitor (fourth configuration).

In the fourth configuration described above, when the analog input voltage is applied to the first bit capacitor or second bit capacitor corresponding to the correction capacitor, a ground potential may be able to be applied to a first bit capacitor or second bit capacitor with the same capacitance as a capacitance of the correction capacitor among the first bit capacitors or the second bit capacitors (fifth configuration).

In the configuration of any of the first to fifth configurations described above, there may be adopted a configuration in which the lower a bit of the first bit capacitor or second bit capacitor corresponding to the bit correction unit, the narrower a capacitance correction range of the bit correction unit (sixth configuration).

In the configuration of any of the first to sixth configurations described above, the at least one second line may include different second lines, and the bit correction unit may include a plurality of the correction capacitors (14, 14A) connected to the different second lines (seventh configuration).

In the configuration of any of the first to seventh configurations described above, the adjustment capacitor may include capacitors connected in parallel via a switch (SW) (eighth configuration: FIG. 9).

An AD converter (10) according to an embodiment of the present disclosure includes a capacitive DAC (1), a comparator (2) into which an output of the capacitive DAC is input, and a control logic unit (3) configured to control the capacitive DAC on the basis of an output of the comparator, in which the capacitive DAC includes a first capacitor (11) as a bit capacitor, and at least one second capacitor (17) connected to the first capacitor, and an analog input voltage and a power supply voltage or a ground potential are able to be selectively applied to the second capacitor (ninth configuration: FIG. 20).

In the ninth configuration described above, the second capacitor may include two second capacitors, and the power supply voltage may be able to be applied to one of the second capacitors while the ground potential may be able to be applied to the other one of the second capacitors (tenth configuration).

In the tenth configuration described above, the two second capacitors may have the same capacitance (eleventh configuration).

An AD converter (10) according to an embodiment of the present disclosure includes a DAC (1), a comparator (2) into which an output of the DAC is input, a control logic unit (3) configured to control the DAC on the basis of an output of the comparator; a decoder (4), and an addition unit (5), in which the control logic unit is configured to determine an additional bit while changing, at least once in units of LSBs, the output of the DAC to a plus side or a minus side after determining a least significant bit, the decoder is configured to output a decoder output according to the least significant bit and the additional bit, and the addition unit is configured to add the decoder output to data including bits from a most significant bit to the least significant bit (twelfth configuration: FIG. 13).

In the twelfth configuration described above, the DAC may be a capacitive DAC, the DAC may include bit capacitors (11), and an additional capacitor (15) that is connected to the bit capacitors and that has the same capacitance as a capacitance of a bit capacitor for the least significant bit among the bit capacitors, and the output of the DAC may be changed in the units of LSBs on the basis of application of a voltage to the additional capacitor (thirteenth configuration).

An AD converter (10) according to an embodiment of the present disclosure includes a DAC (1), a comparator (2) into which an output of the DAC is input, a control logic unit (3) configured to control the DAC on the basis of an output of the comparator, and a low-bit ADC (8) with the number of bits lower than the number of bits of a digital output of the AD converter, in which the low-bit ADC is configured to output a first digital output signal (FLADO) and a second digital output signal (FLADOD) on the basis of an analog input voltage (IN), the second digital output signal is smaller than the first digital output signal by 1 in decimal, and a high-order bit is determined on the basis of an output of the low-bit ADC and an output voltage of the DAC at start of successive approximation for bits following the high-order bit is determined (fourteenth configuration: FIG. 23).

In the fourteenth configuration described above, the low-bit ADC may be a flash ADC, and the low-bit ADC may include a decoder configured to convert a result of comparison between each of a plurality of voltages divided from a reference voltage (REF) and the analog input voltage (IN), into the first digital output signal (FLADO) and the second digital output signal (FLADOD) (fifteenth configuration: FIG. 25).

The present disclosure can be used for AD converters applicable to various systems.

The AD converter according to an embodiment of the present disclosure can improve the AD conversion performance.

What is claimed is:

1. An analog-to-digital converter comprising:
a capacitive digital-to-analog converter into which an analog input voltage is input;
a comparator into which an output of the capacitive digital-to-analog converter is input; and
a control logic unit configured to control the capacitive digital-to-analog converter on a basis of on an output of the comparator,
wherein the capacitive digital-to-analog converter includes
first bit capacitors connected in parallel to a first line,
second bit capacitors connected in parallel to at least one second line,
a connection capacitor connecting the first line and the second line,
an adjustment capacitor connected to the second line, and
a bit correction unit corresponding to at least either the first bit capacitors or the second bit capacitors,
the bit correction unit includes a correction capacitor including a first terminal connected to at least one of the first line and the second line, and
a voltage is able to be applied to a second terminal of the correction capacitor in conjunction with a first bit capacitor or second bit capacitor corresponding to the correction capacitor among the first bit capacitors and the second bit capacitors.

2. The analog-to-digital converter according to claim 1, wherein a voltage with a same logic as a logic for the first bit capacitor or second bit capacitor corresponding to the correction capacitor is able to be applied to the second terminal of the correction capacitor in conjunction with the corresponding first bit capacitor or second bit capacitor.

3. The analog-to-digital converter according to claim 2, wherein, when the analog input voltage is applied to the first bit capacitor or second bit capacitor corresponding to the correction capacitor, the analog input voltage is able to be applied to the second terminal of the correction capacitor.

4. The analog-to-digital converter according to claim 1, wherein a voltage with a logic opposite to a logic for the first bit capacitor or second bit capacitor corresponding to the correction capacitor is able to be applied to the second terminal of the correction capacitor in conjunction with the corresponding first bit capacitor or second bit capacitor.

5. The analog-to-digital converter according to claim 4, wherein, when the analog input voltage is applied to the first bit capacitor or second bit capacitor corresponding to the correction capacitor, a ground potential is able to be applied to a first bit capacitor or second bit capacitor with a same capacitance as a capacitance of the correction capacitor among the first bit capacitors or the second bit capacitors.

6. The analog-to-digital converter according to claim 1, wherein the lower a bit of the first bit capacitor or second bit capacitor corresponding to the bit correction unit, the narrower a capacitance correction range of the bit correction unit.

7. The analog-to-digital converter according to claim 1,
wherein the at least one second line includes different second lines, and
the bit correction unit includes a plurality of the correction capacitors connected to the different second lines.

8. The analog-to-digital converter according to claim 1, wherein the adjustment capacitor includes capacitors connected in parallel via a switch.

9. An analog-to-digital converter comprising:
a capacitive digital-to-analog converter;
a comparator into which an output of the capacitive digital-to-analog converter is input; and
a control logic unit configured to control the capacitive digital-to-analog converter on a basis of an output of the comparator,
wherein the capacitive digital-to-analog converter includes
a first capacitor as a bit capacitor, and
at least one second capacitor connected to the first capacitor, and
an analog input voltage and a power supply voltage or a ground potential are able to be selectively applied to the second capacitor.

10. The analog-to-digital converter according to claim 9,
wherein the second capacitor includes two second capacitors, and
the power supply voltage is able to be applied to one of the second capacitors while the ground potential is able to be applied to the other one of the second capacitors.

11. The analog-to-digital converter according to claim 10, wherein the two second capacitors have a same capacitance.

12. An analog-to-digital converter comprising:
a digital-to-analog converter;
a comparator into which an output of the digital-to-analog converter is input;
a control logic unit configured to control the digital-to-analog converter on a basis of an output of the comparator;
a decoder; and
an addition unit,
wherein the control logic unit is configured to determine an additional bit while changing, at least once in units of least significant bits, the output of the digital-to-analog converter to a plus side or a minus side after determining a least significant bit,
the decoder is configured to output a decoder output according to the least significant bit and the additional bit, and
the addition unit is configured to add the decoder output to data including bits from a most significant bit to the least significant bit.

13. The analog-to-digital converter according to claim 12,
wherein the digital-to-analog converter is a capacitive digital-to-analog converter,
the digital-to-analog converter includes
bit capacitors, and
an additional capacitor that is connected to the bit capacitors and that has a same capacitance as a capacitance of a bit capacitor for the least significant bit among the bit capacitors, and
the output of the digital-to-analog converter is changed in the units of least significant bits on a basis of application of a voltage to the additional capacitor.

14. An analog-to-digital converter comprising:
a digital-to-analog converter;
a comparator into which an output of the digital-to-analog converter is input;
a control logic unit configured to control the digital-to-analog converter on a basis of an output of the comparator; and
a low-bit analog-to-digital converter with the number of bits lower than the number of bits of a digital output of the analog-to-digital converter,
wherein the low-bit analog-to-digital converter is configured to output a first digital output signal and a second digital output signal on a basis of an analog input voltage,
the second digital output signal is smaller than the first digital output signal by 1 in decimal, and
a high-order bit is determined on a basis of an output of the low-bit analog-to-digital converter, and an output voltage of the digital-to-analog converter at start of successive approximation for bits following the high-order bit is determined.

15. The analog-to-digital converter according to claim 14,
wherein the low-bit analog-to-digital converter is a flash analog-to-digital converter, and
the low-bit analog-to-digital converter includes a decoder configured to convert a result of comparison between each of a plurality of voltages divided from a reference voltage and the analog input voltage, into the first digital output signal and the second digital output signal.
